(19) United States
(12) Patent Application Publication
(10) Pub. No.: US 2026/0185209 A1
(43) Pub. Date: Jul. 2, 2026

(54) METHOD OF FORMING AMORPHOUS METAL COATINGS ON STEEL WORKPIECES

(71) Applicant: NANO AND ADVANCED MATERIALS INSTITUTE LIMITED, HONG KONG (CN)

(72) Inventors: Song WANG, HONG KONG (CN); Chen XU, HONG KONG (CN); Tianyu WENG, HONG KONG (CN)

(73) Assignee: NANO AND ADVANCED MATERIALS INSTITUTE LIMITED, HONG KONG (CN)

(21) Appl. No.: 19/262,003

(22) Filed: Jul. 7, 2025

Related U.S. Application Data
(60) Provisional application No. 63/739,102, filed on Dec. 26, 2024.

(51) Int. Cl. C23C 14/16; B32B 15/01; B32B 15/20; C22C 45/02; C23C 14/02; C23C 14/34

(52) U.S. Cl. CPC C23C 14/165; B32B 15/011; B32B 15/013; B32B 15/20; C22C 45/02; C23C 14/021; C23C 14/025; C23C 14/34; B32B 2311/12; B32B 2311/22; B32B 2311/24; B32B 2311/30

(57) ABSTRACT

The present disclosure provides a method for forming a coating on a steel workpiece and a coated steel workpiece prepared by the same. Compared to conventional methods, the comprehensive and innovative method for developing amorphous metal coatings would significantly enhance the lifespan, efficiency, and overall performance of steel workpieces such as cutting instruments.

### CROSS-REFERENCE TO RELATED APPLICATION

This application claims the priority benefit of U.S. provisional application Ser. No. 63/739,102, filed on Dec. 26, 2024. The entirety of each of the above-mentioned patent applications is hereby incorporated by reference herein and made a part of this specification.

### TECHNICAL FIELD

The present disclosure relates to the field of metal coating. More particularly, it relates to a method for forming a coating on a steel workpiece and a coated steel workpiece prepared by the same.

### BACKGROUND

In the food processing industry, cutting instruments such as knives and blades are subjected to rigorous operational conditions, which may lead to significant wear, corrosion, and a consequent reduction in performance over time. Challenges associated with food cutting instruments include: 1) wear and corrosion: cutting instruments are frequently exposed to moisture, acids, and salts present in food, which leads to substantial corrosion and wear; 2) durability: the lack of robust coatings necessitates frequent replacements and maintenance, thereby increasing operational costs. Traditional coatings often fall short in providing the necessary durability and protection required for these applications.

Blade protective coatings are crucial for maintaining the performance and durability of blades used in various applications. These coatings serve as a barrier against corrosion, wear, and other forms of degradation that blades are exposed to during operation. By providing a protective layer, blade coatings may help to extend the lifespan of the blades, thus ensuring they remain functional and efficient over time. Additionally, protective coatings can improve the blade's resistance to harsh environmental conditions, chemicals, and abrasive materials, reducing the need for frequent maintenance and replacement. Blade protective coatings play a vital role in preserving the integrity and performance of blades, ultimately leading to cost savings and enhanced operational efficiency.

Amorphous materials represent a new class of advanced materials that exhibit an attractive combination of properties, such as high strength/hardness and excellent wear/corrosion resistance. These exceptional properties are primarily attributed to the disordered atomic arrangement in amorphous materials, which would result in an absence of grain boundaries and defects in the microstructure. The non-equilibrium nature of amorphous materials confers the outstanding properties. However, it also presents significant challenges in the processing of such materials. While rapid solidification, i.e., casting methods for processing amorphous alloys, is well established, the necessity for simultaneous mold filling and rapid cooling rate limits the range of geometries that can be formed. These processing difficulties, coupled with low tensile ductility and toughness, might restrict the applications of amorphous materials as bulk structural materials. Nonetheless, amorphous materials can serve as excellent candidates for wear/corrosion-resistant coatings on steel substrates.

Therefore, there is an urgent need for an innovative solution that may provide an amorphous metal coating on cutting instruments such as blades, significantly enhancing the lifespan and efficiency of the same.

### SUMMARY

The present disclosure seeks to develop innovative and robust amorphous metal coatings on steel workpieces to overcome at least one of the limitations associated with existing coatings as described in prior art. The inventors have employed three pre-treatment methods to smooth substrate and enhance compatibility, applied an intermediate layer as a bridge between substrate and final coating to further enhance coating adhesion, chose Fe-based coatings characterized by an optimized iron concentration along with small amounts of additional elements, such as chromium, molybdenum, and boron, which may improve the mechanical and chemical properties of coating, and thereby achieved the present disclosure.

As a first aspect of the present disclosure, provided is a method for forming a coating on a steel workpiece, comprising:
1) performing an etching treatment to the steel workpiece to obtain an etched steel workpiece;
2) performing an electropolishing treatment to the etched steel workpiece by using the etched steel workpiece as an anode to obtain an electropolished steel workpiece;
3) performing a plasma treatment to the electropolished steel workpiece to obtain a plasma treated steel workpiece;
4) depositing an intermediate layer on the surface of the plasma treated steel workpiece to obtain a steel workpiece with the intermediate layer; and
5) depositing an amorphous metal coating on the steel workpiece with the intermediate layer, wherein the amorphous metal coating is comprised of an amorphous alloy selected from the group consisting of: a zirconium-based amorphous alloy, a copper-based amorphous alloy, a nickel-based amorphous alloy, an aluminum-based amorphous alloy, a titanium-based amorphous alloy, an iron-based amorphous alloy, or a palladium-based amorphous alloy.

As a second aspect of the present disclosure, provided is a coated steel workpiece, comprising:
a steel substrate;
an intermediate layer on the surface of the steel substrate; and
an amorphous metal coating on the surface of the steel substrate with the intermediate layer;
wherein the coated steel workpiece is formed by the method according to the first aspect.

In the present disclosure, the inventor provides a novel and robust method for developing amorphous metal coatings on steel workpieces, specifically so as to improve blade performance and longevity. The method includes a comprehensive pre-surface treatment process followed by a PVD coating process, forming an intermediate layer and an amorphous metal coating. A coated steel workpiece prepared by the method features multiple advantages, such as:
improved bonding strength: the comprehensive three-step pre-treatment processes may significantly increase the surface energy and improve the compatibility between coating and substrate, ensuring a robust and long-lasting finish;
exceptional durability: the inclusion of an intermediate layer and an optimized alloy coating formula may result in superior abrasion resistance and the ability to withstand rigorous conditions;
superior corrosion and wear resistance: an iron-based coating with additional elements such as chromium, molybdenum, and boron may provide excellent resistance to corrosion and wear, ensuring the steel workpiece to maintain its performance over time;
extremely low coefficient of friction: Nanoscratch testing reveals the iron-based coating's surface has an exceptionally smooth surface texture, with a very low coefficient of friction, which not only enhances its hardness and durability but also significantly reduces heat generation during use. This, in turn, minimizes wear and tear, further extending the coating's lifespan;
potent antibacterial properties: the iron-based coating demonstrates strong antibacterial activity against common bacteria like Staphylococcus aureus and Escherichia coli, with antibacterial rates exceeding 99.99% as per ISO 22196 standards. This indicates the coating's significant inhibitory effects, improving hygiene and safety in applications such as food processing;

In conclusion, the disclosure offers a comprehensive and innovative method for developing amorphous metal coatings that may significantly enhance the lifespan, efficiency, and overall performance of steel workpieces, such as cutting instruments.

### BRIEF DESCRIPTION OF THE DRAWINGS

The accompanying drawings are included to provide a further understanding of the disclosure and are incorporated in and constitute a part of this specification. The drawings described herein are for illustration purposes only and are not intended to limit the scope of the disclosure in any way.

FIG. 1 illustrates the appearance of a Fe-31 protective coating after 48 hours of exposure to salt spray environment.

FIG. 2 illustrates an adhesion test result of a coating according to one embodiment of the present disclosure following the Daimler-Benz Rockwell-C(HRC-DB) test standard (left panel-standard; right panel—the test results of the sample).

### DETAILED DESCRIPTION

The present disclosure will be clearly and completely described below by reference to the embodiments of the present disclosure and the accompanying drawings. Obviously, the described embodiments are only some of the embodiments of the present disclosure, and not all of them. Based on the embodiments of the present disclosure, all other embodiments available to the ordinary skilled in the art fall into the scope of the present disclosure. Also, it is to be understood that the phraseology and terminology employed herein is for the purpose of description and should not be regarded as limiting.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard variation found in their respective testing measurements.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

As used herein, the singular forms “a”, “an” and “the” include plural forms, unless the context clearly dictates otherwise specified or clearly implied to the contrary by the context in which the reference is made. The expressions “a/the first”, “a/the second”, “a/the third” and the like are only for the purpose of distinction, but not seek to define any order, priority, or grade.

As used herein, the terms “about” and “substantially” are used herein with respect to measurable values and ranges due to expected variations known to those skilled in the art (e.g., limitations and variability in measurements). The term “about” also indicates that the stated numerical value allows some slight imprecision (with some approach to exactness in the value; approximately or reasonably close to the value; nearly). If the imprecision provided by the term “about” is not otherwise understood in the art with this ordinary meaning, then the term “about” as used herein indicates at least variations that may arise from ordinary methods of measuring and using such parameters. In addition, disclosure of ranges includes disclosure of all values and further divided ranges within the entire range.

As used herein, the term “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

As used herein, the term “consisting of” and its grammatical variations should be understood in the context of the present disclosure to exclude the presence of any unspecified element, ingredient or method step. As used herein, the term “consisting essentially of” and its grammatical variations should be understood in the context of the present disclosure to include the specified elements, materials, ingredients or method steps and those that do not materially affect the basic and novel characteristic(s) of what is being described. It shall be understood that, when the term “comprising” and its grammatical variations are used and no additional elements, materials, ingredients or method steps that may materially affect the basic and novel characteristic(s) of what is being described are included, then the term “comprising” can be replaced with the term “consisting of” or “consisting essentially of” and their grammatical variations.

Whereas specific aspects of the disclosure are going to be described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the disclosure, which is to be given the full breadth of the claims appended and any and all equivalents thereof.

As mentioned above, the present disclosure aims to provide an innovative and robust amorphous metal coatings on steel workpieces to overcome at least one of the limitations associated with existing coatings as described in prior art.

As a first aspect of the present disclosure, provided is a method for forming a coating on a steel workpiece, comprising:
1) performing an etching treatment to the steel workpiece to obtain an etched steel workpiece;
2) performing an electropolishing treatment to the etched steel workpiece by using the etched steel workpiece as an anode to obtain an electropolished steel workpiece;
3) performing a plasma treatment to the electropolished steel workpiece to obtain a plasma treated steel workpiece;
4) depositing an intermediate layer on the surface of the plasma treated steel workpiece to obtain a steel workpiece with the intermediate layer; and
5) depositing an amorphous metal coating on the steel workpiece with the intermediate layer, wherein the amorphous metal coating is comprised of an amorphous alloy selected from the group consisting of: a zirconium-based amorphous alloy, a copper-based amorphous alloy, a nickel-based amorphous alloy, an aluminum-based amorphous alloy, a titanium-based amorphous alloy, an iron-based amorphous alloy, or a palladium-based amorphous alloy.

It is understood by those skilled in the art that the method of the present application can be applied on various types of steel workpiece, i.e., steel substrate, including but not limited to carbon steel, high speed steel, pearlitic steel and austenitic steel.

It is understood by those skilled in the art that surface pretreatment methods are crucial steps in preparing metal surfaces for subsequent coating processes, which enhance the adhesion, durability, and overall performance of coatings. In the present disclosure, the inventors have employed three pre-treatment methods: etching, electropolishing and plasma treatments, which collectively enhance the bonding strength and the durability of coatings applied to metal surfaces.

Firstly, a steel substrate is subjected to an etching treatment, which is a chemical process, in which the metal is immersed in an acidic or alkaline solution to selectively remove material from the surface to form a microstructure similar to the surface of a lotus leaf.

Subsequently, the steel substrate is subjected to an electropolishing treatment, which is an electrochemical finishing process that removes a thin surface layer of material from metal parts. The process results in a smoother and cleaner surface. The electropolishing process could level peaks and valleys and provide improvement in surface roughness. Unlike mechanical finishing, electropolishing does not smear, bend, stress or fracture the crystalline metal surface. Also, surface defects could be deburred and removed. Electropolishing could remove small pieces of displaced surface material that could seize and break on a microscopic level.

Finally, the steel substrate is subjected to a plasma treatment, which is a surface modification process and is effective in enhancing adhesion by modifying the surface properties of materials, making them more receptive to coatings or adhesives. When using plasma treatment in an air atmosphere, the reactive species generated in the plasma can clean the surface, remove contaminants, and activate the surface by creating functional groups that promote bonding.

In an embodiment, the etching treatment in 1) is performed in an etching solution containing ferric chloride.

In the context of the present disclosure, it is understood that the term “amorphous metal”, also known as metallic glasses, refers to a unique class of materials characterized by their non-crystalline atomic structure. Unlike traditional crystalline metals, which have atoms arranged in a regular, repeating lattice structure, amorphous metals have a disordered atomic arrangement. The absence of grain boundaries and dislocations contributes to exceptional strength and hardness of amorphous metals, and the disordered atomic structure enhances resistance to wear and corrosion, making them ideal for coatings.

Fe-based amorphous metal coatings are a type of metallic glass coating, which is primarily composed of Fe along with other elements like Ni, Cr, Co, Si, B and Nb. Fe-based amorphous metals may present ultrahigh strength. Appropriate composition can be optimized by fine-tuning the composition of a formulation. Amorphous metal coatings are enhanced with Sn additives to lower the coefficient of friction, improve tribological performance, and promote a smoother surface. The addition of chromium and molybdenum enhances corrosion resistance by forming protective oxide layers, while copper or aluminium additives are utilized for their antibacterial properties, disrupting bacterial cells effectively. These additives play crucial roles in optimizing the performance of amorphous metal coatings in various applications.

In an embodiment, the amorphous metal coating in 5) is comprised of an iron-based amorphous alloy.

In an embodiment, the iron-based amorphous alloy is comprised of 30-50 at. % Fe, 10-25 at. % Cr, 10-20 at. % Mo, 10-20 at. % Ti, 5-15 at. % B, 5-15 at. % C, 3-8 at. % Si, 0-10 at. % Co and 0-5 at. % Y (at. %=Atomic Percentage).

In this disclosure, the inventors selected various Fe-based amorphous metal coatings based on the percentage of iron in alloy to examine their performance, including Fe-31 (Fe₃₁Cr₁₅Mo₁₄C₁₀B₁₀Si₅Ti₁₅), Fe-41 (Fe₄₁Cr₁₅Co₇Mo₁₄C₁₂B₉Y₂), Fe-44 (Fe₄₄Cr₁₅Mo₁₄C₁₀B₅Si₅Co₇) and Fe-46 (Fe₄₆Cr₂₃Mo₁₄B₅Si₅Co₇). Among above coatings, Fe-31 coating shows the most stable performance.

In a particular embodiment, the iron-based amorphous alloy is comprised of Fe₃₁Cr₁₅Mo₁₄C₁₀B₁₀Si₅Ti₁₅.

In a particular embodiment, the iron-based amorphous alloy is comprised of Fe₄₁Cr₁₅Co₇Mo₁₄C₁₂B₉Y₂.

In a particular embodiment, the iron-based amorphous alloy is comprised of Fe₄₄Cr₁₅Mo₁₄C₁₀B₅Si₅Co₇.

In a particular embodiment, the iron-based amorphous alloy is comprised of Fe₄₆Cr₂₃Mo₁₄B₅Si₅Co₇.

In the development of Fe-based amorphous metal coatings, a significant challenge identified was the adhesion between a coating and a substrate. Direct application of Fe-based amorphous metal coatings onto a stainless steel surface resulted in poor adhesion, as evidenced by failure during tape testing. An intermediate layer is crucial for ensuring strong adhesion between a coating and a substrate, as poor adhesion can lead to issues like peeling, corrosion, and cracking, even if the coating itself performs exceptionally well. To enhance the adhesion of the coating, it is essential to match the properties of the intermediate layer with both the coating material and the substrate, including factors like the thermal expansion coefficient (TEC) and mechanical properties. Mismatched TEC between the substrate and coating can result in significant stresses during temperature changes, leading to debonding and failure of the coating. By selecting an intermediate layer with a TEC that matches both the coating and substrate, these stresses can be minimized, improving bond strength and stability. Materials such as Ti, Al, etc. are commonly used as buffer or adhesive layers due to their TEC values, helping to strengthen the bond between the coating and substrate and ensuring long-term performance and durability.

In this application, the inventors evaluated the effectiveness of Cu, Al, Ti or TiO as intermediate layer materials for enhancing the adhesion of Fe-based amorphous metal coatings according to TEC of substrate and protective coating. The results demonstrated that samples with Al and Ti intermediate layer exhibited markedly improved adhesion properties.

In an embodiment, the intermediate layer in 4) is comprised of Cu, Al, Ti or TiO (99.9% Pure). In an embodiment, the intermediate layer in 4) is comprised of Al or Ti. Given superior corrosion resistance of Ti, preferably, it is selected as the optimal intermediate layer material for the subsequent PVD process in the protective coating application.

Physical vapor deposition (PVD), sometimes being called as physical vapor transport (PVT), describes a variety of vacuum deposition methods, which can be used to produce thin films and coatings on substrates. PVD is characterized by a process in which the material transitions from a condensed phase to a vapor phase and then back to a thin film condensed phase, and is widely used for its ability to produce high-quality, durable coatings with excellent adhesion and performance characteristics. Compared to traditional chemical coating methods, PVD processes generate minimal hazardous waste.

In an embodiment, the intermediate layer and the amorphous metal coating are respectively deposited on the plasma treated steel workpiece by using a physical vapor deposition (PVD) method.

Sputtering is one of the most common PVD processes, where atoms are ejected from a target material (a source) due to bombardment by energetic particles, usually ions of an inert gas like argon, and the ejected atoms then travel through a vacuum chamber and deposit onto a substrate, forming a thin film. Sputtering provides uniform, high-quality, multilayer coatings with excellent adhesion and controlled composition, making it ideal for this application.

In a particular embodiment, the PVD method is sputtering.

It is known to those skilled in the art that sputtering techniques include magnetron sputtering, radio frequency (RF) sputtering, direct current (DC) sputtering, reactive sputtering, and other types. RF sputtering is a process that uses radio frequency alternating current power to enhance the efficiency and control of the sputtering process. Unlike conventional DC sputtering, which uses direct current power, RF sputtering creates a magnetic field around the deposition source and ionizes the process gas atoms. Therefore, RF sputtering has a wider range of applications and is suitable for all the materials for conductive and non-conductive materials. However, it is most commonly used for depositing dielectric sputtering target materials. The RF-sputtered film is smoother and has better packing density than a DC-sputtered film. In the present application, the intermediate layer is comprised of Cu, Al, Ti or TiO, which are not all conductive, so it is more suitable to use RF sputtering, but if the intermediate layer is comprised of a conductive material, it can also be deposited by DC sputtering.

In an embodiment, the intermediate layer is deposited on the plasma treated steel workpiece by radio frequency (RF) sputtering or direct current (DC) sputtering. In a particular embodiment, the sputtering is performed in an argon atmosphere at 0.1-1 Pa and 2-4 W/cm² for 5-20 min, preferably, the sputtering is performed in an argon atmosphere at 0.3 pa and 2.55 W/cm² for 10 min.

The amorphous metal coating, such as Fe-based amorphous metals protective coating, can be synthesized by a number of methods, including laser irradiation, spray coating and other methods. In some embodiments, protective coatings are directly deposited by direct current (DC) magneto-sputtering with Fe-based amorphous metals targets (99.9% Pure). As mentioned above, it is more suitable to adopt DC sputtering since all the materials involved are metallic materials. DC sputtering has a higher deposition rate and thus is effective and economical for pure metal sputtering targets.

In an embodiment, the amorphous metal coating is deposited on the steel workpiece with the intermediate layer by direct current (DC) sputtering. In a particular embodiment, the DC sputtering is performed in an argon atmosphere at 0.1-1 Pa and 2-4 W/cm² for 40-100 min, preferably, the DC sputtering is performed in an argon atmosphere at 0.3 pa and 2.55 W/cm² for 60 min.

In an embodiment, the steel workpiece is a cutting instrument. In a particular embodiment, the cutting instrument is a blade.

As a second aspect of the present disclosure, provided is a coated steel workpiece, comprising:
a steel substrate;
an intermediate layer on the surface of the steel substrate; and
an amorphous metal coating on the surface of the steel substrate with the intermediate layer;
wherein the coated steel workpiece is formed by the method according to the first aspect.

In an embodiment, the intermediate layer has a thickness of 0-100 nm.

In an embodiment, the amorphous metal coating has a thickness of 100-900 nm.

### EXAMPLES

Within this specification, examples have been described in a way which enables a clear and concise specification to be written, but it is intended and will be appreciated that examples may be variously combined or separated without parting from the disclosure. For example, it will be appreciated that all preferred features described herein are applicable to all aspects of the disclosure described herein.

### Example 1: Preparation of an Amorphous Metal Coating on Steel Workpiece

The blade surface protective coating fabrication includes a 3-step pre-treatment, which are etching, electropolishing and plasma treatment, followed up by intermediate layer and protective coating deposition, respectively. Pre-treatment procedures increase the surface energy and improve the compatibility between the coating and substrate. An intermediate layer enhances coating adhesion by bridging the substrate and coating and amorphous protective coatings are ideal for blade applications due to their corrosion resistance, high hardness, and good adhesion properties.

The method of the present application can be applied on various types of steel substrate. In this example, the blade protective coatings were fabricated on stainless steel sheets for testing purpose. The stainless steel sheets, with size of 50 mm*50 mm*1 mm, were undergone rigorous cleaning before subsequent use, including 10 minutes of ultrasonic cleaning with acetone, 10 minutes of ultrasonic cleaning with alcohol, and 10 minutes of ultrasonic cleaning with distilled water. After cleaning, the stainless steel sheets were dried in a 70-° C. thermostat.

### 1.1 Pre-Treatment Step 1: Etching

The chemical etchant was formulated in the following proportions with iron (III) chloride 16 g, distilled water 60 mL, hydrogen chloride acid 2 mL, phosphoric acid 2 mL and hydrogen peroxide 2 mL. Using a magnetic stirrer to stir the obtained solution until homogeneous. The prepared chemical etchant can be stored in a glass container.

During the etching process, firstly, the stainless steel sheets were immersed in the prepared chemical etchant, and kept it in a 50-C water bath for 60 minutes. Then, the treated stainless steel sheets were all undergone rigorous cleaning to remove etchant, including 10 minutes of ultrasonic cleaning with acetone, 10 minutes of ultrasonic cleaning with alcohol, and 10 minutes of ultrasonic cleaning with distilled water. The stainless steel sheets were all dried in a 70-C thermostat after cleaning.

During the etching process, iron easily reacts with hydrochloric acid and ferric chloride to corrode the surface of stainless steel to form a microstructure similar to the surface of a lotus leaf. The above pre-treated stainless steel sheets were then ready for the following two pre-treatments.

### 1.2 Pre-Treatment Step 2: Electropolishing

Electrolytes used for pre-treatment typically consist of a highly viscous mixture of sulfuric and phosphoric acids. In detail, before starting to prepare the electrolyte, enough ice cubes and ice water should be prepared to cool down the acid during the mixing process, so as to avoid accidents caused by concentrated acid boiling or splashing out of the container. Firstly, 765 ml of concentrated phosphoric acid with a concentration of 85%, was weighed and slowly poured into a glass container of appropriate size. Secondly, 435 ml of concentrated sulfuric acid with a concentration of 95% was weighed and slowly poured into the concentrated phosphoric acid, and stirred with a glass rod or magnet while pouring. This process was carried out in an ice bath by using the ice water and ice cubes to cool the outside of the container in time to avoid accidents. Thirdly, when the acid was mixed evenly and the temperature dropped to room temperature, 8.3424 grams of polyethylene glycol 6000, 2.0856 grams of hexamethylenetetramine, 10.428 grams of citric acid, 0.20856 grams of thiourea, 12 milliliters of glycerin and 48 milliliters of water, were added and fully stirred to be mixed evenly. Finally, a clear and transparent electrolyte was obtained and stored in a glass container.

During the electropolishing process, the metal part acted as a positively charged anode. The above treated stainless steel sheet after pre-treatment step 1 was connected to the positive terminal of the DC power rectifier. The negatively charged cathode, typically made of zirconium, was connected to the negative terminal of the DC power rectifier. Both the anode and cathode were immersed in a temperature-controlled bath of above prepared electrolyte solution. The temperature was kept under 70° C. and the power is kept at 5 V for 40 seconds for each stainless steel sheet in pre-treatment 2.

After electropolishing process, microscopic smoothness of the stainless steel sheets could be improved.

### 1.3 Pre-Treatment Step 3: Plasma Treatment

Firstly, the electropolished stainless steel sheets were placed in a plasma chamber. Secondly, the plasma chamber was evacuated to create a low-pressure environment. Thirdly, the inventors introduced air to create the plasma atmosphere and apply radiofrequency or microwave energy to generate the plasma. And at last, the stainless steel sheets were treated for 30 mins to achieve the desired surface modification. This process resulted in improved adhesion by increasing surface energy and creating a more chemically reactive surface for better bonding with coatings or adhesives.

### 1.4 Coating Layer 1: Intermediate Layer

The pre-treated stainless steel sheets were put inside the chamber and reached a base environmental pressure level at least 10-4 Pa. The pressure was then increased to 0.3 Pa with Ar atmosphere and the flow rate was kept at 80 sccm during the whole sputtering process. The sputtering RF power was kept at 200 W.

### 1.5 Coating Layer 2: Protective Coating

The pre-treated stainless steel sheets with the intermediate layer were put inside the chamber and reached a base environmental pressure level at least 10-4 Pa. The pressure was then increased to 0.3 Pa with Ar atmosphere and the flow rate was kept at 80 sccm during the whole sputtering process. The sputtering DC power was under the fixed 200 W.

TABLE 1
Preferred parameters in sputtering

| Layer | Target | Air | Pressure | Power | Duration |
|---|---|---|---|---|---|
| Intermediated | Ti | Ar | 0.3 Pa | RF | 10 min |
| | | | | 2.55 W/cm² | |
| Protective | Fe-31 | Ar | 0.3 Pa | DC | 60 min |
| | | | | 2.55 W/cm² | |

*Note:
Fe-31 refers to Fe-31 (Fe₃₁Cr₁₅Mo₁₄C₁₀B₁₀Si₅Ti₁₅).

### Example 2: Performance Tests of the Coatings

After the amorphous metal coatings were prepared according to the procedure of Example 1 using the Fe-31 coating and the Ti intermediate layer with parameters mentioned in Table 1, the coatings were subjected to the following performance tests:

### Test for Hardness

According to the standard of ISO 14577-1:2015, the coatings were tested for hardness by a nano indentation test, and the results are shown in Table 2.

The typical steps for conducting a nano indentation test include preparing the sample surface through polishing, calibrating the indenter, performing the indentation by applying a controlled load while measuring the depth of penetration, and finally analyzing the load-displacement data to extract relevant mechanical properties.

The hardness data for all samples was systematically calculated to evaluate the effectiveness of protective coatings. To assess the performance of selected protective coatings, a detailed investigation was conducted on four distinct stainless steel samples, designated as A, B, C, and D, each representing varying surface conditions encountered in industrial applications. A is a 301 stainless steel, B is a 420 stainless steel, C is a kind of 440 stainless steel and D is another kind of 440 stainless steel. In addition, A, B, C, and D have different roughness, with A being the smoothest and D being the roughest.

The results indicated that sample A, in its bare state, exhibited an average hardness of 6.2 GPa (57 HRC), which increased to 13.5 GPa following the application of the protective coating. Sample B, in its uncoated state, displayed an average hardness of 6.8 GPa (60 HRC), with a subsequent increase to 13.1 GPa after coating. For sample C, the hardness rose from 5.6 GPa (54 HRC) to 12.5 GPa post-coating, while sample D showed an increase from 4.9 GPa (49 HRC) to 12.3 GPa. Overall, the original hardness values for the samples ranged from 4 to 7 GPa, whereas post-coating hardness values increased significantly to between 12 and 14 GPa.

TABLE 2
Test results of a nano indentation

| Sample | Bare (Gpa) | Coated (Gpa) |
|---|---|---|
| A | 6.2 Gpa | 13.5 Gpa |
| B | 6.8 Gpa | 13.1 Gpa |
| C | 5.6 Gpa | 12.5 Gpa |
| D | 4.9 Gpa | 12.3 Gpa |

### Test for Corrosion Resistance

Corrosion resistance test in the examples followed the standard of GB/T10125. Typical steps for conducting a salt spray test include preparing a sample by cleaning and drying it, placing it in a salt spray chamber, and subjecting it to a continuous mist of a sodium chloride solution (5%) at a specified temperature and humidity for a predetermined duration. After the exposure period, the samples are removed and assessed for signs of corrosion, such as rust formation or coating degradation, allowing for an evaluation of their corrosion resistance properties.

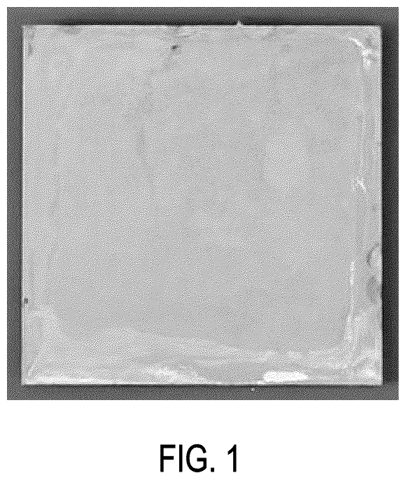

In preliminary in-house corrosion resistance assessments, a sample coated with Fe-31 protective coating (Fe₃₁Cr₁₅Mo₁₄C₁₀B₁₀Si₅Ti₁₅) demonstrated exceptional performance after a 6-hour exposure to a 5% NaCl corrosive solution, exhibiting no visible signs of corrosion. Following a 24-hour exposure period, the sample maintained its structural integrity, indicating sustained protective efficacy. Furthermore, in a third-party salt spray test conducted in accordance with the GB/T10125 standard, the sample coated with Fe-31 protective coating remained in excellent condition after 48 hours of exposure to the salt spray environment (as shown in FIG. 1). This performance validated the effectiveness of the Fe-31 protective coating in enhancing corrosion resistance.

### Test for Adhesion

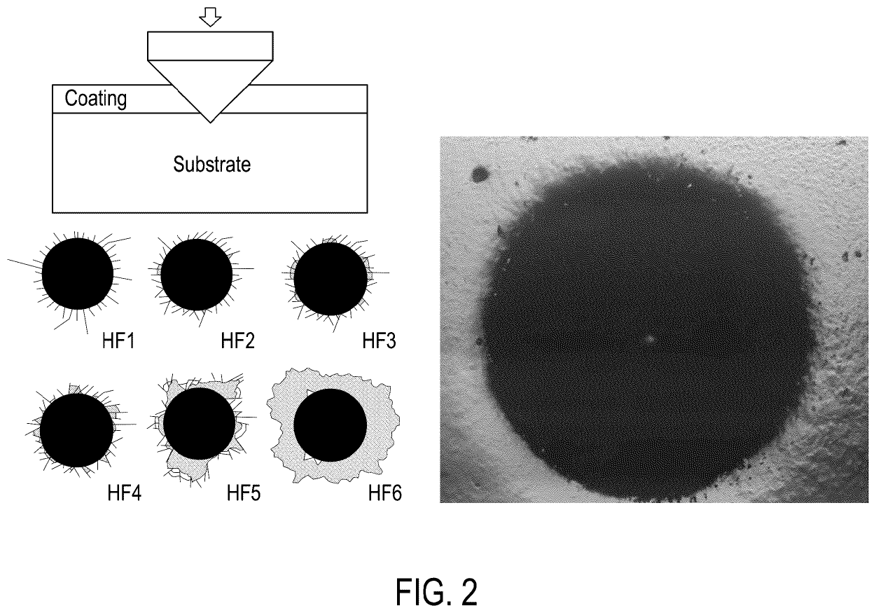

Adhesion test in the examples followed the Daimler-Benz Rockwell-C(HRC-DB) test standard. According to the established standard, a cone indenter with a diameter of 0.2 mm was utilized, applying a load of 1470 N onto sample surface. During the imaging process, it was imperative that all images were captured with consistent pixel sizes to ensure comparability. The indent was positioned approximately at the center of the test image, and scale bars were excluded to maintain clarity. Furthermore, the minimum height or width of the image, whichever was smaller, should be no less than twice the diameter of the indent to ensure adequate resolution for analysis. By comparing the captured images against standard reference images (left panel in FIG. 2), the adhesion of the coating could be classified into categories HF1, HF2, HF3, HF4, HF5, and HF6, with HF1 being the best and HF6 being the worst, which provided a systematic framework for assessing the quality of coating adhesion. According to the adhesion test image of our protective coating (right panel in FIG. 2), compared with the standard image, adhesion of the protective coating reached the optimal level of coating adhesion of the standard, HF=1. The results are shown in FIG. 2.

### Test for Sharpness and Durability

Sharpness test in the example followed the standard of ISO 8442-5:2004. According to ISO 8442-5:2004, the blade's performance, measured by the distance cut through the medium on each cycle, was tracked throughout the duration of the test. The blades cut an adequate amount of medium to complete the test. The two cutting performance indicators, ICP (initial cutting performance) and CER (cutting edge retention), were calculated based on the accumulated data. ICP was measured by the cutting depth after three cuts, while CER was measured by the cutting depth after 200 cuts using the same cutting force. The ICP and CER of the bare blade were recorded as 16.61 mm and 72.57 mm, respectively, while the ICP and CER of the Fe-31 coated blade were recorded as 23.68 mm and 77 mm. The test results indicated that the fruit knife with the protective coating significantly increased both sharpness and durability.

### Test for Coefficient of Friction

Coefficient of friction test in the example followed nanoscratch test procedure. According to nanoscratch test procedure, by applying a controlled load with a sharp indenter on the sample surface while simultaneously recording the lateral and normal forces using the equipment of nano indenter. The coefficient of friction is then calculated using the ratio of the lateral force to the normal load. The test results indicate that the surface of the Fe-31 coating exhibits a coefficient of friction of approximately 0.18, suggesting a very smooth surface texture that enhances both its hardness and durability. A lower coefficient of friction reduces heat generation during use, which further improves the coating's longevity by minimizing wear and tear.

### Test for Anti-Bacterial Performance

Anti-bacterial test in the example followed the standard of ISO 22196. According to ISO 22196, average of the common logarithm of the number of viable bacteria recovered from the untreated test specimens immediately after inoculation (U₀), average of the common logarithm of the number of viable bacteria recovered from the untreated test specimens after 24 h (Uₜ), and average of the common logarithm of the number of viable bacteria recovered from the treated test specimens after 24 h (Aₜ) are recorded. Then the antibacterial activity R can be calculated at R=(Uₜ−U₀)−(Aₜ−U₀)=Uₜ−Aₜ. And antibacterial rate can be calculated at (Uₜ−Aₜ)/Uₜ.

The test results demonstrated that the Fe-31 coating exhibits an antibacterial activity rating (R) of 5.8 and an antibacterial rate exceeding 99.99% against Staphylococcus aureus, as well as an antibacterial activity rating (R) of 6.1 and an antibacterial rate exceeding 99.99% against Escherichia coli. These testing results indicate that the fabricated coating possesses significant antibacterial properties against both S. aureus and E. coli.

Food grade tests are crucial in blade applications to ensure safety, compliance with regulations, durability, hygiene, and effective performance in food processing. Food grade tests are conducted according to United States Food and Drug Administration (US FDA) CFR 175.300 & CPG 7117.05 & ICP-OES. First, extracts of chloroform in 8% ethanol, water, and n-heptane were tested to be lower than the limitation. Second, soluble lead (Pb) in 4% acetic acid was tested and also met the requirement. Third, the total chromium percentage is 16.2, which meets the requirement of being greater than 10.5. These food grade tests demonstrate that the coatings are safe for use with food-grade blade applications.

What is claimed is:

1. A method for forming a coating on a steel workpiece, comprising:
1) performing an etching treatment to the steel workpiece to obtain an etched steel workpiece;
2) performing an electropolishing treatment to the etched steel workpiece by using the etched steel workpiece as an anode to obtain an electropolished steel workpiece;
3) performing a plasma treatment to the electropolished steel workpiece to obtain a plasma treated steel workpiece;
4) depositing an intermediate layer on the surface of the plasma treated steel workpiece to obtain a steel workpiece with the intermediate layer; and
5) depositing an amorphous metal coating on the steel workpiece with the intermediate layer, wherein the amorphous metal coating is comprised of an amorphous alloy selected from the group consisting of: a zirconium-based amorphous alloy, a copper-based amorphous alloy, a nickel-based amorphous alloy, an aluminum-based amorphous alloy, a titanium-based amorphous alloy, an iron-based amorphous alloy, or a palladium-based amorphous alloy.

2. The method according to claim 1, wherein the amorphous metal coating in 5) is comprised of an iron-based amorphous alloy.

3. The method according to claim 2, wherein the iron-based amorphous alloy is comprised of 30-50 at. % Fe, 10-25 at. % Cr, 10-20 at. % Mo, 10-20 at. % Ti, 5-15 at. % B, 5-15 at. % C, 3-8 at. % Si, 0-10 at. % Co and 0-5 at. % Y.

4. The method according to claim 3, wherein the iron-based amorphous alloy is comprised of Fe₃₁Cr₁₅Mo₁₄C₁₀B₁₀Si₅Ti₁₅.

5. The method according to claim 3, wherein the iron-based amorphous alloy is comprised of Fe₄₁Cr₁₅Co₇Mo₁₄C₁₂B₉Y₂.

6. The method according to claim 3, wherein the iron-based amorphous alloy is comprised of Fe₄₄Cr₁₅Mo₁₄C₁₀B₅Si₅Co₇.

7. The method according to claim 3, wherein the iron-based amorphous alloy is comprised of Fe₄₆Cr₂₃Mo₁₄B₅Si₅Co₇.

8. The method according to claim 1, wherein the intermediate layer in 4) is comprised of Cu, Al, Ti or TiO, preferably Al or Ti, and most preferably Ti.

9. The method according to claim 1, wherein the etching treatment in 1) is performed in an etching solution containing ferric chloride.

10. The method according to claim 1, wherein the intermediate layer and the amorphous metal coating are respectively deposited on the treated steel workpiece by using a physical vapor deposition (PVD) method such as sputtering.

11. The method according to claim 10, wherein the intermediate layer is deposited on the treated steel workpiece by radio frequency (RF) sputtering or direct current (DC) sputtering, preferably, the sputtering is performed in an argon atmosphere at 0.1-1 Pa and 2-4 W/cm² for 5-20 min, more preferably, the sputtering is performed in an argon atmosphere at 0.3 pa and 2.55 W/cm² for 10 min.

12. The method according to claim 10, wherein the amorphous metal coating is deposited on the treated steel workpiece by direct current (DC) sputtering, preferably, the DC sputtering is performed in an argon atmosphere at 0.1-1 Pa and 2-4 W/cm² for 40-100 min, more preferably, the DC sputtering is performed in an argon atmosphere at 0.3 pa and 2.55 W/cm² for 60 min.

13. The method according to claim 1, wherein the steel workpiece is a cutting instrument such as a blade.

14. A coated steel workpiece, comprising:
a steel substrate;
an intermediate layer on the surface of the steel substrate; and
an amorphous metal coating on the surface of the steel substrate with the intermediate layer;
wherein the coated steel workpiece is formed by the method according to claim 1.

15. The coated steel workpiece according to claim 14, wherein the intermediate layer has a thickness of 0-100 nm.

16. The coated steel workpiece according to claim 14, wherein the amorphous metal coating has a thickness of 100-900 nm.
